(19) United States
(12) Patent Application Publication
(10) Pub. No.: US 2011/0052832 A1
(43) Pub. Date: Mar. 3, 2011

(54) FILM FORMING METHOD AND FILM FORMING APPARATUS

(75) Inventors: Yousuke KOBAYASHI, Chigasaki-shi (JP); Nobuhiro HAYASHI, Chigasaki-shi (JP); Masayuki IIJIMA, Chigasaki-shi (JP); Isao TADA, Chigasaki-shi (JP)

(73) Assignee: ULVAC, INC., Chigasaki-shi (JP)

(21) Appl. No.: 12/877,327

(22) Filed: Sep. 8, 2010

Related U.S. Application Data
(63) Continuation of application No. PCT/JP2009/057494, filed on Apr. 14, 2009.

(30) Foreign Application Priority Data
Apr. 25, 2008 (JP) 2008-115290

(51) Int. Cl. C23C 16/00; C23C 16/513

(52) U.S. Cl. 427/488; 118/723 VE

(57) ABSTRACT

An object of the present invention is to provide a reflection film formation technology which achieves the simplification of an apparatus structure and the cost reduction thereof. A film forming method of the present invention includes a reflection film formation step (P2) for forming a reflection film having light reflecting properties by vapor deposition onto an object to be film-formed, while introducing air into a film forming region; a polymer film formation step (P3) for forming a water-repelling polymer film on the reflection film; and a hydrophilized treatment step (P5) for performing a hydrophilized treatment by a plasma onto the water-repelling polymer film, while introducing air into the film forming region. According to the present invention, formation of the reflection film and the hydrophilized treatment of the polymer film can be performed without using argon gas.

This application is a continuation of International Application No. PCT/JP2009/57494 filed Apr. 14, 2009, which claims priority to Japanese Patent Document No. 2008-115290, filed on Apr. 25, 2008. The entire disclosure of the prior applications are herein incorporated by reference in their entireties.

### BACKGROUND

The present invention relates to a technology for forming a film by vapor deposition in a vacuum, and more particularly, to a technology for forming a reflection film using a reflection mirror.

Conventionally, when manufacturing a reflection mirror of this type, such a method is used which includes the steps of introducing an argon (Ar) gas into a vacuum chamber and forming a reflection film by vapor deposition on an object to be film-formed, then forming a polymer film on the reflection film by introducing a monomer for forming water-repelling polymer film into the vacuum chamber, and further performing a hydrophilized treatment of the surface of the polymer film using a plasma of the argon gas (see, for example, JPA2003-207611).

In recent years, there has been a demand for the simplification of the configuration of the film-forming apparatus for the manufacturing such a reflection mirror and the cost reduction thereof; and research and development for this purpose have progressed.

### SUMMARY OF THE INVENTION

The present invention was made to solve problems of such a prior art; and the aim is to provide a reflection film formation technology, which enables the simplification of apparatus configuration and for cost reduction.

The present inventors, as the result of the earnest attempts to solve the above-described problems, found the formation of a film comparable to a film by using argon gas, by performing a vapor deposition and a hydrophilized treatment using a gas containing oxygen; and have thus completed the present invention.

The present invention which was made based on such a finding is a film forming method including the steps of a reflection film formation step for forming a reflection film having light reflecting properties by vapor deposition on an object to be film-formed, while introducing a process gas containing oxygen into a film forming region; a polymer film formation step for forming a water-repelling polymer film on the reflection film; and hydophilized treatment step for performing a hydrophilized treatment by plasma onto the water-repelling polymer film, while introducing a process gas containing oxygen into a film forming region.

According to another aspect of the present invention, the process gas to be introduced in the hydrophilized treatment step in the above-described invention, is air.

According to still another aspect of the present invention, the process gas to be introduced in the reflection film formation step in the above-described invention is air.

According to still another aspect of the present invention, the object to be film-formed in the above-described invention is a three-dimensional member constituting the reflection mirror.

On the other hand, according to still another aspect of the present invention, there is provided a film forming apparatus including a vacuum processing chamber which can accommodate an object to be film-formed; a process gas introduction unit, connected to the vacuum processing chamber for introducing a process gas containing oxygen; a monomer introduction unit connected to the vacuum processing chamber for introducing monomer for forming a water-repelling polymer film; an evaporation source provided inside the vacuum processing chamber; and a plasma generation source provided inside the vacuum processing chamber.

According to still another aspect of the present invention, the process gas introduction unit in the above-described invention introduces air in the vicinity of the vacuum processing chamber.

In the present invention, the hydrophilized treatment is performed by the plasma on the water-repelling polymer film in the process gas containing oxygen, so that reactivity can be enhanced by using an active radical, as compared to the case that uses conventional argon gas. As a result, electric power to be applied during the hydrophilized treatment step to the water-repelling polymer film can be reduced; and accordingly, electric power cost can be reduced.

Further, according to the present invention, cost of the process gas in the formation of the reflection film and the hydrophilized treatment can be reduced by using air as the process gas. Furthermore, because piping for the process gas becomes unnecessary, simplification of the apparatus structure and cost reduction of the film forming apparatus can be achieved.

In addition, since safety measures (such as, prevention of an oxygen deficiency) becomes unnecessary with the use of air as the process gas, it is possible to provide a film forming apparatus which is easy to handle.

According to the present invention, it is possible to provide a reflection film formation technology which enables the simplification of an apparatus configuration and for cost reduction thereof.

### BRIEF DESCRIPTION OF THE DRAWINGS

FIG. 1 is a cross-sectional view illustrating an internal configuration of a film forming apparatus of the present exemplary embodiment.

FIG. 2 is a flowchart illustrating an example of a film forming method according to the present invention.

FIGS. 3(a) to 3(d) are cross-sectional views illustrating the configurations of films formed by the film forming method of the present invention.

### DETAILED DESCRIPTION OF THE INVENTION

Hereinafter, a preferable exemplary embodiment of the present invention will be described in detail with reference to the drawings.

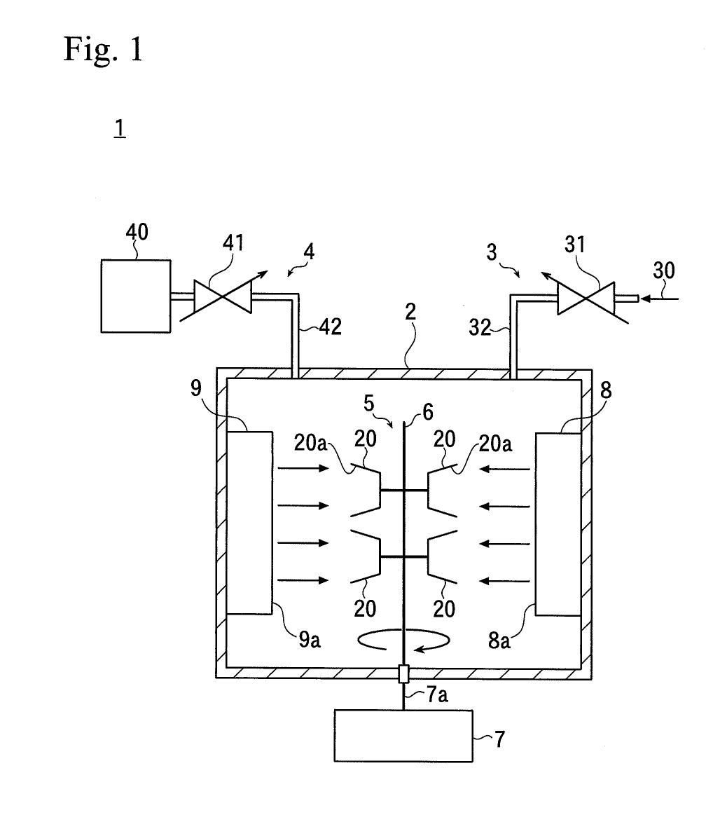

FIG. 1 is a cross-sectional view illustrating an internal structure of a film forming apparatus of the present exemplary embodiment.

As shown in FIG. 1, a film forming apparatus 1 of the present exemplary embodiment has a vacuum processing chamber (film forming region) 2 connected to a vacuum exhaust system (not shown).

A process gas introduction unit 3 and a monomer introduction unit 4, which are provided outside the vacuum processing chamber 2, respectively, are connected to the vacuum processing chamber 2.

The process gas introduction unit 3 is configured such that an introducing pipe 32 is connected to the vacuum processing chamber 2 via a flow regulating valve 31 in order to introduce a predetermined amount of air 30 into the vacuum processing chamber 2 from an atmosphere in the vicinity of the vacuum processing chamber 2.

The monomer introduction unit 4 has a monomer supply source 40, which supplies the monomer for forming the water-repelling polymer film. The monomer supply source 40 is configured such that an introducing pipe 42 is connected to the monomer supply source 40 via a flow regulating valve 41; and a predetermined amount of the monomer is introduced into the vacuum processing chamber 2 via the introducing pipe 42.

A holding mechanism 5 for holding the object to be film-formed 20 is provided inside the vacuum processing chamber 2.

The holding mechanism 5 of the present exemplary embodiment has, for example, a straight-shaped holding unit 6 provided in vertical direction at the central region of the vacuum processing chamber 2.

The holding unit 6 is configured such that it is connected to a rotation shaft 7a of a drive motor 7 provided outside the vacuum processing chamber 2, and film-forming surfaces 20a of a plurality of objects to be film-formed 20 are rotated with respect to the rotation shaft 7a while being held toward an outward direction.

An evaporation source 8 is provided on a side wall portion inside the vacuum processing chamber 2. The evaporation source 8 is arranged such that a vapor discharge surface 8a thereof faces the film-forming surfaces 20a of respective objects to be film-formed 20. In this regard, the evaporation source 8 has a filament-shaped evaporation material (not shown) made of, for example, aluminum (Al).

Furthermore, on the side wall portion inside the vacuum processing chamber 2, a plasma generation source 9 having AC power source (not shown) is provided. The plasma generation source 9 is arranged such that a plasma ejection surface 9a thereof faces the film-forming surfaces 20a of the respective objects to be film-formed 20.

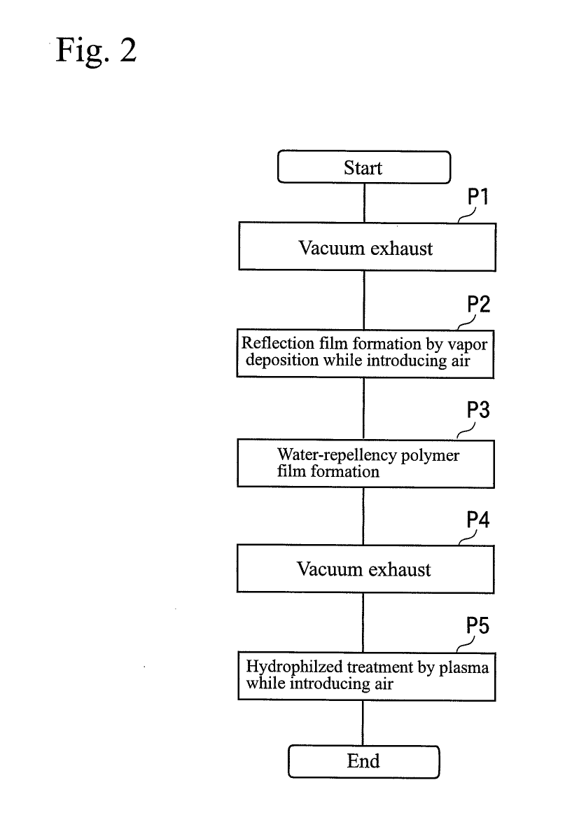

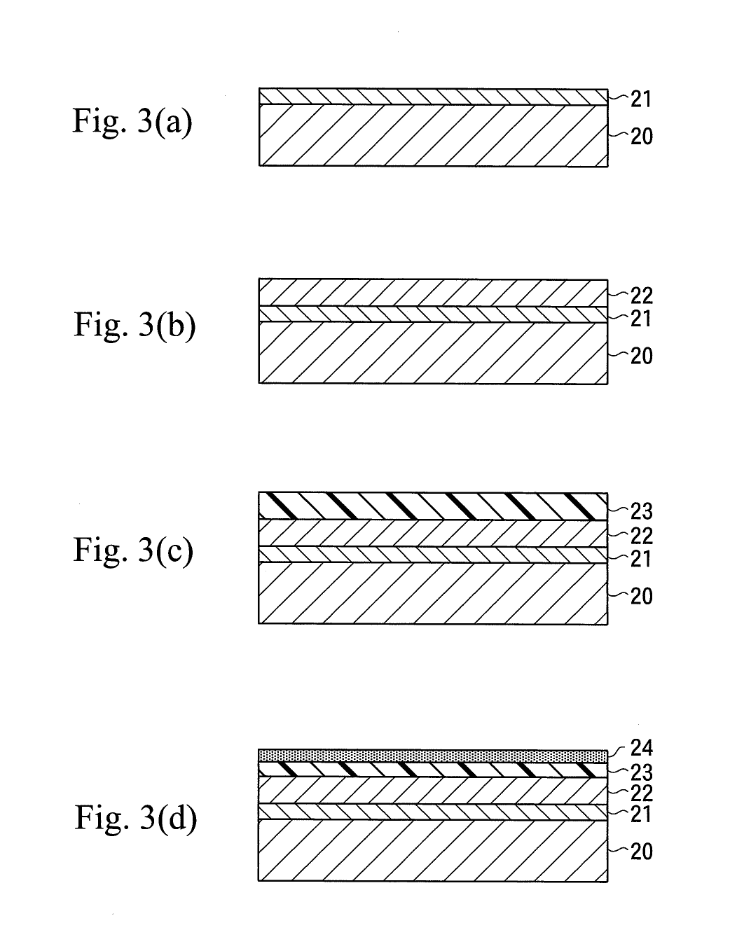

FIG. 2 is a flowchart illustrating an example of a film forming method according to the present invention. FIGS. 3(a) to 3(d) are cross-sectional views illustrating the structures of films formed by the same film forming method of the present invention.

In this example, a case of forming a film onto the object to be film-formed 20 having an undercoat layer 21, as shown in FIG. 3(a), using the film forming apparatus 1 as shown in FIG. 1 will be described as an example.

First, in a process P1, the inside of the vacuum processing chamber 2 is vacuum-exhausted to attain a predetermined pressure (for example, 1×10⁻² Pa).

Next, air is introduced into the vacuum processing chamber 2 by controlling the flow regulating valve 31 (process P2).

In the case of the present invention, a pressure inside the vacuum processing chamber 2 is not specifically limited; however, it is preferably adjusted within a range of 5.0×10⁻² Pa to 1.0 Pa from a viewpoint of enhancing the uniform formation of film on the object to be film-formed 20 having a three-dimensional shape.

Then, the vapor deposition is performed while the holding mechanism 5 is operated in order to rotationally move the object to be film-formed 20 (process P2). During the vapor deposition, a pressure inside the vacuum processing chamber 2 is maintained, while air is introduced and exhaust is performed at the same time.

As a consequence, as shown in FIG. 3(b), the reflection film 22 made of aluminum is formed on the undercoat layer 21 of the object to be film-formed 20.

Next, the flow regulating valve 41 is controlled so as to supply raw material monomer for polymer film formation into the vacuum processing chamber 2 from the monomer supply source 40; and a plasma generation source 9 is operated while the object to be film-formed 20 is rotationally moved, so that a water-repelling polymer film 23 is formed on the reflection film 22 (process P3, FIG. 3(c)).

The water-repelling polymer film 23 functions as a protective film having alkali resistance for preventing oxidation and corrosion of the reflection film 22. As a raw material monomer thereof, monomers containing silicon (such as, hexametyldisiloxane (HMDSO) or the like) can be suitably used.

Then, the inside of the vacuum processing chamber 2 is vacuum-exhausted (process P4).

Next, the flow regulating valve 31 is controlled so that air is introduced into the vacuum processing chamber 2 in order to attain a predetermined pressure (process P5).

In the present invention, pressure inside the vacuum processing chamber is not particularly limited. However, it is preferable to adjust the pressure inside the vacuum processing chamber 2 within the range of 0.1 Pa to 10 Pa in order to maintain suitable plasma.

Then, the plasma generation source 9 is operated (for example, 40 kHz to 13.56 MHz), in order to generate oxygen plasma, and nitrogen plasma inside the vacuum processing chamber 2; and a hydrophilized polymer film 24 is formed on the surface of the water-repelling polymer film 23 as shown in FIG. 3(d) by exposing the surface of the water-repelling polymer film 23 of the object to be film-formed 20 to oxygen and nitrogen plasma (process P5). During the plasma processing, pressure inside the vacuum processing chamber 2 is maintained, while air is introduced and exhaust is performed at the same time.

In the present exemplary embodiment as discussed above, because the hydrophilic treatment is performed by plasma on the water-repelling polymer film 23 using air as a processing gas containing oxygen, reactivity can be enhanced by using an active radical (O₂, N₂), as compared to the conventional case of using argon gas. As a result, electric power to be applied in the hydrophilized treatment step onto the water-repelling polymer film 23 can be decreased; and accordingly, electric power cost can be reduced.

Furthermore, according to the present exemplary embodiment, because air is used as the process gas, the costs of the process gas in the reflection film formation step and the hydrophilized treatment step can be reduced. Also, because piping or the like for the process gas becomes unnecessary, simplification of the apparatus configuration and cost reduction for the film forming apparatus can be achieved.

Furthermore, since safety measures (such as, prevention of oxygen deficiency or the like) becomes unnecessary by using air as the process gas, the film forming apparatus that can be easily handled can be provided.

It is to be noted that the present invention is not limited to the exemplary embodiment as described above, but various modifications may be provided.

For example, in the exemplary embodiment as described above, air is used as the process gas, but the present invention is not limited thereto. It is possible to use, for example, a gas made of only oxygen, as long as the gas contains oxygen.

Further, it is possible to use air as the process gas in either the reflection film formation step or the hydrophilized treatment step.

However, due to cost reduction of the process gas, simplification of the apparatus configuration and reduction of the apparatus cost, similar to the above-discussed exemplary embodiment, it is preferable to use air in both the reflection film formation step and the hydrophilized treatment step.

Further, in the present exemplary embodiment as described above, air is introduced during the reflection film formation process by vapor deposition and during the hydrophilized treatment process. However, if moisture in the air or the like varies depending on location and climate, air which has been subjected to drying processing or air from an air cylinder can also be supplied.

In addition, nitrogen gas can also be used as a process gas which can be used at a lower cost as compared to Ar. However, when taking into account that there is no need for remedies (such as, oxygen deficiency processing), it is preferable to use air (gas containing oxygen) as discussed above.

Further, in the above-described exemplary embodiment, the reflection film formation step and the hydrophilized treatment step are performed in the same vacuum processing chamber. The present invention, however, also includes the case where the reflection film formation step and the hydrophilized treatment step are performed in different vacuum processing chambers.

### Example

Hereinafter, an Example of the present invention will be described in detail together with a comparative Example.

### <Effect of Air Introduction During the Reflection Film Formation Process>

In the apparatus as illustrated in FIG. 1, using the same amount of aluminum as an evaporation material, vapor deposition is performed with respect to an object to be film-formed having a three-dimensional shape with varied pressures, and the uniform formation of the film is determined through visual observation. The result is shown in Table 1.

Here, ∘ is marked to signify the result in which the thickness of a film on a vertical surface relative to an evaporation source was adequate as a reflecting surface, and x is marked to signify the result in which the thickness of the film was inadequate as a reflecting surface and darkening occurred.

TABLE 1
Determination result of uniform formation of
films by varied vapor deposition pressure

| | Vapor deposition | Uniform formation |
|---|---|---|
| | pressure (Pa) | of film |
| Air introduced | 1.0 × 10⁻¹ | ◯ |
| No gas introduced | 2.0 × 10⁻² | X |

As clearly seen in Table 1, it is found that the uniform formation of films to the object to be film-formed is improved by the introduction of air into the vacuum processing chamber (pressure 1.0×10⁻¹ Pa).

### <Effect of Air Introduction During the Hydrophilized Treatment Process>

In the apparatus as shown in FIG. 1, using an HMDSO as a raw material monomer of the water-repelling polymer film, a polymer film having a thickness of 300 angstroms is formed onto an object to be film-formed having a three-dimensional shape. Furthermore, a plasma is generated by introducing air or argon gas, and the hydrophilized treatment is performed (frequency: 40 kHz).

Then, respective objects to be film-formed are soaked in aqueous solution of 1% KOH for ten minutes; and alkali resistances of hydrophilized polymer films are evaluated. The result is shown in Table 2.

Here, ∘ is marked to signify the result in which the aluminum was not discolored after it was soaked in the aqueous solution of 1% KOH for ten minutes, and x is marked to signify the result of discoloration.

Furthermore, contact angles were measured by visual observation for respective objects to be film-formed which have been subjected to the above-described hydrophilized treatment. The result is shown in Table 2.

TABLE 2
Evaluation result of alkali resistance and contact angle in hydrophilic treatment condition

| Condition of hydrophilic treatment | | | | | Result of hydrophilic treatment | |
|---|---|---|---|---|---|---|
| Kind of | Pressure | Power source | Vdc of | | Alkali | |
| gasses | (Pa) | output (kw) | discharge (v) | Time (s) | resistance | Contact angle |
| Ar | 1 | 3 | 790 | 5 | ◯ | 45° |
| Air | 1 | 3 | 430 | 5 | X | 20° |
| Air | 1 | 1 | 350 | 5 | ◯ | 30° |

Alkali resistance: Soaked in 1% KOH solution for 10 minutes

As clearly seen in Table 2, if air is introduced in the hydrophilized treatment, hydrophilized processing of good contact angle (30°) can be performed by applying lower electric power (1 kW) as compared to the case in which argon gas is introduced.

By the above-discussed description, the effects of the present invention could be confirmed.

What is claimed is:

1. A film forming method, comprising:
a reflection film formation step for forming a reflection film having light reflecting properties by vapor deposition on an object to be film-formed, while introducing a process gas containing oxygen into a film forming region;
a polymer film formation step for forming a water-repelling polymer film on the reflection film; and
a hydrophilized treatment step for performing a hydrophilized treatment by plasma onto the water-repelling polymer film, while introducing a process gas containing oxygen into a film forming region.

2. The film forming method according to claim 1, wherein the process gas to be introduced in the hydrophilized treatment step is air.

3. The film forming method according to claim 1, wherein the process gas to be introduced in the reflection film formation step is air.

4. The film forming method according to claim 2, wherein the process gas to be introduced in the reflection film formation step is air.

5. The film forming method according to claim 1, wherein the object to be film-formed is a three-dimensional member including a reflection mirror.

6. A film forming apparatus, comprising:
a vacuum processing chamber which can accommodate an object to be film-formed;
a process gas introduction unit for introducing a process gas containing oxygen, wherein the process gas introduction unit is connected to the vacuum processing chamber;
a monomer introduction unit for introducing monomer for forming a water-repelling polymer film, wherein the monomer introduction unit is connected to the vacuum processing chamber;
an evaporation source arranged inside the vacuum processing chamber; and
a plasma generation source arranged inside the vacuum processing chamber.

7. The film forming apparatus according to claim 6, wherein the process gas introduction unit introduces air in the vicinity of the vacuum processing chamber.
